(19) United States
(12) Patent Application Publication
(10) Pub. No.: US 2025/0346727 A1
(43) Pub. Date: Nov. 13, 2025

(54) MEMBER FOR ELECTRONIC DEVICE HOUSING

(71) Applicant: Toray Industries, Inc., Tokyo (JP)

(72) Inventors: Wataru Yamamoto, Nagoya-shi, Aichi (JP); Nobuyuki Komatsu, Nagoya-shi, Aichi (JP); Hiroyuki Nakayama, Nagoya-shi, Aichi (JP)

(73) Assignee: Toray Industries, Inc., Tokyo (JP)

(21) Appl. No.: 18/868,933

(22) PCT Filed: Jun. 20, 2023
(86) PCT No.: PCT/JP2023/022695

§ 371 Date: Nov. 25, 2024

(30) Foreign Application Priority Data
Jun. 30, 2022 (JP) 2022-105275

(51) Int. Cl. C08J 5/04; B32B 5/02; B32B 5/18; B32B 5/24; B32B 5/26; C08J 5/24; H05K 5/02

(52) U.S. Cl. CPC C08J 5/042; B32B 5/022; B32B 5/18; B32B 5/245; B32B 5/26; B32B 5/265; C08J 5/046; C08J 5/243; C08J 5/248; H05K 5/02; B32B 2260/023; B32B 2260/046; B32B 2262/0253; B32B 2262/106; B32B 2262/16; B32B 2266/025; B32B 2439/00; B32B 2457/00; C08J 2323/26; C08J 2363/00; C08J 2369/00

(57) ABSTRACT

A member for an electronic device housing that includes a plate-like component having a fiber-reinforced plastic and a thermoplastic resin component integrated with at least a part of the peripheral edge region of the plate-like component, wherein the thermoplastic resin component contains reinforcing fibers A and a thermoplastic resin D, a part of the reinforcing fibers A are dispersed as single fibers, and another part of the reinforcing fibers A are not dispersed as single fibers and are arranged randomly in a shape of a convergence part E formed from a plurality of single fibers. This disclosure makes it possible to provide a member for an electronic device housing having a satisfactory impact resistance.

### CROSS REFERENCE TO RELATED APPLICATIONS

This application is a US national stage filing under 35 U.S.C. § 371 of International Application No. PCT/JP2023/022695, filed Jun. 20, 2023, which claims priority to Japanese Patent Application No. 2022-105275, filed Jun. 30, 2022, each of which is incorporated herein by reference in its entirety.

### TECHNICAL FIELD

This disclosure relates to a member for an electronic device housing.

### BACKGROUND

Fiber-reinforced plastics (FRP) comprising reinforcing fibers and a matrix resin are widely utilized in various industrial applications because of their excellent light weight and mechanical properties. At the present time, as electrical and electronic devices such as personal computers, office automation equipment, AV equipment, mobile phones, telephones, facsimiles, home appliances and toys become more portable, there is a demand for further miniaturization and weight reduction. To meet this demand, the components forming the devices, particularly the housings, are required to achieve high strength and high rigidity while being thin-walled so that the housing does not bend significantly when an external load is applied, causing contact with internal components and destruction. In a molded structure that is made small and lightweight by integrally joining and molding a fiber-reinforced resin structure comprising reinforcing fibers and a resin with another member, such as a frame member, there is a demand for a further thinning without warping and reliable joining strength.

To reduce weight, many technologies have been proposed, such as means for using a low-density material for a core layer of a layered body with a sandwich structure to reduce the specific gravity of the entire product, and means for providing voids inside a sandwich-like structure to reduce the density of the entire product.

JP-B-6447127 proposes that in an integrally molded body having a bonding resin interposed between a plate material, one surface of which is a design surface, and a member, the plate material and the member are arranged so as to be spaced apart from each other, the outer peripheral edge portion of the plate material has a joint portion which is joined to the bonding resin, and at least a part of the surface of the design surface side of the integrally molded body has a region where the plate material, the member, and the bonding resin are exposed, so that multiple structures are joined with a high bonding strength, the joining boundary has a good smoothness, and warping is attempted to be reduced even when the molded body has a component of a plate material.

JP-A-2006-181776 proposes using fiber-reinforced resin pellets using reinforcing fibers with different fiber lengths to increase the filling rate of the reinforcing fibers and improve mechanical properties, flowability, appearance, and productivity.

Further, remnants and scraps generated during the manufacturing process of FRP products, and waste materials comprising FRP products which are to be discarded, are difficult to be recycled due to their nature, and are generally crushed or incinerated and then disposed in landfills. Problems such as landfill sites and environmental hormones generated from epoxy resins have become social issues. To establish recycling technologies, thermal recycling, in which waste materials, remnants and the like are incinerated and the heat energy obtained during incineration is recovered, and material recycling, in which a part of these waste materials are added to raw materials when manufacturing other products, and reused, are being investigated.

JP-A-2017-002125 proposes a method for providing recycled carbon fiber bundles that have a convergence property causing no problem for passing a process, and excellent in reinforcing effect, and excellent even in dispersibility in matrix resin, by thermally decomposing a matrix resin of CFRP waste materials and heat treating so that the weight of the resin residue is 0.1 to 6% of the carbon fiber bundles.

However, the bonding resin used in JP-B-6447127 does not necessarily improve the physical properties of the resulting molded body sufficiently. Further, the method in JP-A-2006-181776 aims to uniformly disperse reinforcing fibers and has no concept of converging the reinforcing fibers. In addition, although it is described that recovered materials can be used as short fiber-reinforced thermoplastic resin pellets, there is no concept of reusing the molded product.

The batch-type heat treatment proposed in JP-A-2017-002125 is insufficient for mass production and is costly, and when crushing and heat treatment are continuously performed to improve mass production, the convergence property is insufficient, and the handling property is insufficient, such as clogging in a process, which makes its industrial use unsuitable. Moreover, the advantage of using recycled carbon fiber bundles as reinforcing fibers compared to use of virgin materials has not been demonstrated.

It could therefore be helpful to provide a member for an electronic device housing having an impact resistance that is less likely to crack when subjected to impacts, particularly applied when the electronic device housing is dropped, in a member for an electronic device housing comprising a plate-like component having a fiber-reinforced plastic and a thermoplastic resin component integrated with at least a part of the peripheral edge region of the plate-like component.

### SUMMARY

We thus provide:
(1) A member for an electronic device housing including a plate-like component having a fiber-reinforced plastic and a thermoplastic resin component integrated with at least a part of a peripheral edge region of the plate-like component, wherein the thermoplastic resin component contains reinforcing fibers A and a thermoplastic resin D, a part of the reinforcing fibers A are dispersed as single fibers, and another part of the reinforcing fibers A are not dispersed as single fibers and are arranged randomly in a shape of a convergence part E formed from a plurality of single fibers.
(2) The member for an electronic device housing according to (1), wherein a content of the reinforcing fibers A in the thermoplastic resin component is 1 to 50% by mass.
(3) The member for an electronic device housing according to (1) or (2), wherein a resin H different from the thermoplastic resin D is attached to surfaces of the single fibers forming the convergence part E at an amount of 0.1 to 30% by mass with respect to 100% by mass of the reinforcing fibers A contained in the convergence part E.
(4) The member for an electronic device housing according to any of (1) to (3), wherein an average fiber diameter of the single fibers in the reinforcing fibers A in the thermoplastic resin component is 4.0 to 30.0 μm.
(5) The member for an electronic device housing according to any of (1) to (4), wherein the plate-like component is a sandwich structural body comprising a core material and a fiber-reinforced plastic joined to both surfaces of the core material.
(6) The member for an electronic device housing according to any of (1) to (5), wherein the reinforcing fibers A contain two kinds of reinforcing fibers B and reinforcing fibers C different from each other in average fiber diameter of single fibers, the reinforcing fibers B do not form the convergence part E, a part of the reinforcing fibers C disperse as single fibers, and another part of the reinforcing fibers C form the convergence part E.
(7) The member for an electronic device housing according to (6), wherein a mass ratio B/C of the reinforcing fibers B to the reinforcing fibers C is 99/1 to 40/60.

It is possible to obtain a member for an electronic device housing having a good impact resistance as an electronic device housing.

### BRIEF DESCRIPTION OF THE DRAWINGS

FIG. 1 is a schematic diagram of a member for an electronic device housing according to an example.

FIG. 2 is a schematic perspective view showing a partial cross section of the member for an electronic device housing shown in FIG. 1;

FIG. 3 is a schematic perspective view showing a partial cross section of a member for an electronic device housing according to another example, which uses a plate-like component having a sandwich structure.

FIG. 4 is a schematic perspective view showing a partial cross section of a member for an electronic device housing according to a further example, in which a thermoplastic resin component has a rib shape.

### EXPLANATION OF SYMBOLS

1: member for an electronic device housing
2: plate-like component
3: thermoplastic resin component
4: convergence part E
5: skin material
6: core material
7: uneven shape (rib shape)

Hereinafter, our member will be explained concretely with reference to the drawings. However, this disclosure is not limited to the following examples and drawings, and can be carried out with appropriate modifications within the scope of its purpose.

The member for an electronic device housing is a member for an electronic device housing comprising a plate-like component having a fiber-reinforced plastic, and a thermoplastic resin component integrated with at least a part of a peripheral edge region of the plate-like component, wherein the thermoplastic resin component comprises reinforcing fibers A and a thermoplastic resin D, a part of the reinforcing fibers A are dispersed as single fibers, and another part of the reinforcing fibers A are not dispersed as single fibers and are arranged randomly in a shape of a convergence part E formed from a plurality of single fibers.

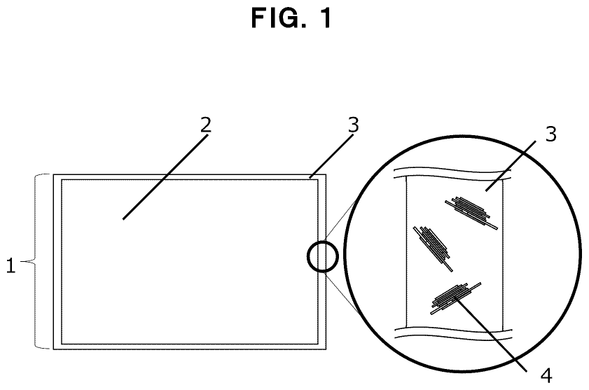

An example of a member for an electronic device housing is shown in FIG. 1. In FIG. 1, a member for an electronic device housing 1 is formed by integrating a plate-like component 2 and a thermoplastic resin component 3, and a convergence part E 4 is included in the thermoplastic resin component 3.

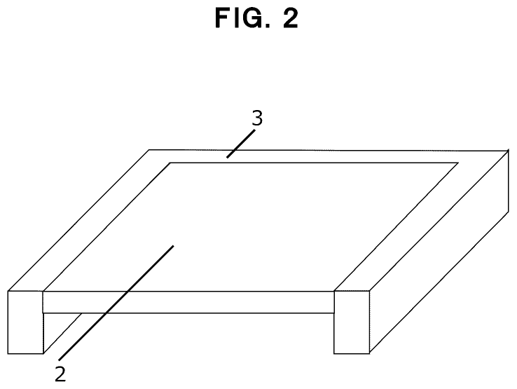

Further, FIG. 2 shows the member for an electronic device housing of FIG. 1 as viewed from another angle. In FIG. 2, it is shown that the thermoplastic resin component 3 is integrated with the peripheral edge part of the plate-like component 2.

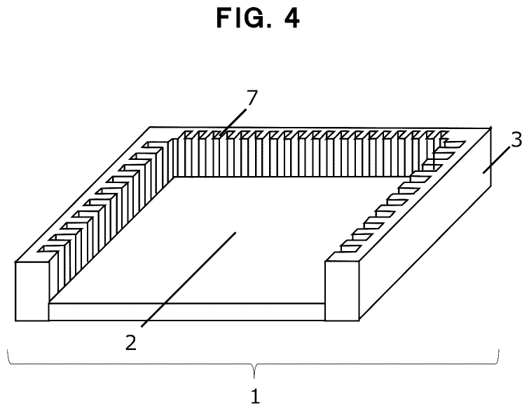

Further, FIG. 4 shows another example of a member for an electronic device housing. FIG. 4 is a schematic perspective view showing a partial cross section of the member for an electronic device housing 1 when the thermoplastic resin component 3 has an uneven shape 7 (rib shape) for reinforcement. In the example shown in FIG. 4, the uneven shape 7 (rib shape) is formed on the inside (plate-like component 2 side) of the thermoplastic resin component 3, and the outer surface can be used as a design surface, but for the purpose of reinforcement, the uneven shape 7 (rib shape) can also be provided on the outside of the thermoplastic resin component 3 or on a part of the inside or outside.

### Plate-Like Component

The term “plate-like” in the plate-like component means an appropriately flat plate, and indicates that the aspect ratio of the long side to the thickness of the plate-like component is equal to or greater than 10. The plate-like component may have unevenness or holes in a part thereof, an arch shape or a slope, or may have different thicknesses.

At least a part of the plate-like component is made of a fiber-reinforced plastic in which reinforcing fibers are impregnated with a thermosetting resin or a thermoplastic resin.

The plate-like component has a fiber-reinforced plastic. Namely, at least a part of the plate-like article comprises a fiber-reinforced plastic in which reinforcing fibers are impregnated with a thermosetting resin or a thermoplastic resin.

The fiber-reinforced plastic may be composed of a fiber-reinforced plastic alone, or may be a sandwich structural body comprising a core material and a fiber-reinforced plastic joined to both surfaces of the core material. In the sandwich structural body, the plate-like component as a whole can be made lighter while maintaining its rigidity by making the core material with a material having a low specific gravity. Furthermore, from the viewpoint of light weight, among sandwich structural bodies, a sandwich structural body in which the core material is a sheet-like intermediate base material in which a reinforcing fiber mat is impregnated with a thermosetting resin or a thermoplastic resin, or a foamed material having voids, is preferred.

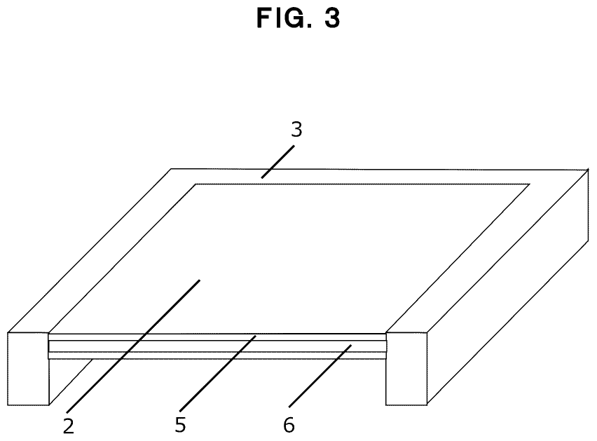

An example of a member for an electronic device housing using a plate-like component having a sandwich structure is shown in FIG. 3. FIG. 3 is a schematic perspective view showing a partial cross section of a plate-like component 2 having a sandwich structure comprising a skin material 5 and a core material 6, in which the plate cross section can be seen.

The above-described reinforcing fiber mat preferably employs a nonwoven fabric form. By employing a nonwoven fabric form, the reinforcing fiber mat can be easily impregnated with a thermosetting resin or a thermoplastic resin, and the effect of anchoring the reinforcing fiber mat to the thermosetting resin or the thermoplastic resin is enhanced and it is likely to have an excellent joining property. The nonwoven fabric form indicates a form in which strands and/or monofilaments of the reinforcing fibers are dispersed in a planar shape without regularity. As examples of the nonwoven fabric form, exemplified are chopped strand mats, continuous strand mats, papermaking mats, carding mats, air laid mats, and the like. The reinforcing fibers in the reinforcing fiber mat may be the same as or different from the reinforcing fibers used in a skin material. Where, the skin material indicates a fiber-reinforced plastic joined to both surfaces of a core material in a sandwich structural material.

As examples of the resin constituting the above-described foamed material, exemplified are polyurethane resin, phenol resin, melamine resin, acrylic resin, polyethylene resin, polypropylene resin, polyvinyl chloride resin, polystyrene resin, acrylonitrile-butadiene-styrene (ABS) resin, polyetherimide resin, polymethacrylimide resin, etc. Among them, it is preferred to use a resin having an apparent density smaller than that of a skin material in order to ensure light weight. Specifically, polyurethane resin, acrylic resin, polyethylene resin, polypropylene resin, polyetherimide resin, and polymethacrylimide resin are preferable.

As examples of the thermosetting resin used in the fiber-reinforced plastic, for example, exemplified are unsaturated polyester resin, vinyl ester resin, epoxy resin, phenol resin, urea resin, melamine resin, polyimide resin, cyanate ester resin, bismaleimide resin, benzoxazine resin, copolymers or modified products thereof, resins obtained by blending at least two of these resins, etc. Among these, epoxy resins are preferred because of their excellent mechanical properties, thermal resistance, and adhesiveness with reinforcing fibers.

As examples of the thermoplastic resin used in the fiber-reinforced plastic, for example, exemplified are styrene-based resins, fluoro resins, polyoxymethylene, polyamide, polyester, polyimide, polyamideimide, vinyl chloride, olefin-based resins, thermoplastic elastomers, polyacrylate, polyphenylene ether, polycarbonate, polyethersulfone, polyetherimide, polyetherketone, polyetheretherketone, polyarylene sulfide, cellulose derivatives such as cellulose acetate, cellulose acetate butyrate and ethyl cellulose, liquid crystalline resins, and modified materials or blends of two or more of these.

The reinforcing fibers used in the fiber-reinforced plastic may be continuous reinforcing fibers or reinforcing fibers that partially contain discontinuous reinforcing fibers. The continuous reinforcing fibers indicate reinforcing fibers that are continuous in at least one direction with a length of 100 mm or more. Further, an aggregate of many reinforcing fibers arranged in one direction, a so-called reinforcing fiber bundle, is continuous over the entire length of a plate-like component. The discontinuous reinforcing fibers indicate fibers that are not continuous in one direction with a length of 100 mm or more, and the arrangement directions of the many fibers are different.

As examples of the reinforcing fibers used in the fiber-reinforced plastic, for example, exemplified are metal fibers such as aluminum, brass and stainless steel; polyacrylonitrile (PAN)-based, rayon-based, lignin-based and pitch-based carbon fibers; graphite fibers; insulating fibers such as glass; organic fibers such as aramid, polyparaphenylene benzobisoxazole (PBO), polyphenylene sulfide, polyester, acrylic, nylon and polyethylene; inorganic fibers such as silicon carbide and silicon nitride, and the like.

The reinforcing fibers used in the fiber-reinforced plastic may be surface-treated. As the surface treatment, for example, in addition to coating with a metal as a conductor, exemplified are a treatment with a coupling agent, a treatment with a sizing agent, a treatment with a binder, a treatment with an additive, or the like.

In particular, from the viewpoint of effect for weight reduction, PAN-based, pitch-based, rayon-based carbon fibers, which are excellent in specific strength and specific rigidity, are preferably used. Further, from the viewpoint of increasing the electrical conductivity of the resulting molded product, reinforcing fibers coated with a metal such as nickel, copper, or ytterbium can also be used.

The reinforcing fibers used in the fiber-reinforced plastic may be of one kind alone or in combination of two or more kinds.

To improve adherence with the thermoplastic resin component, it is also preferred that the plate-like component preferably comprises a thermoplastic resin layer as needed. Further, the plate-like component may also contain a different-kind material such as a metal depending upon the purpose.

As one example of a method for manufacturing a plate-like component having a fiber-reinforced plastic, exemplified is a method in which prepregs containing an uncured thermosetting resin, or thermoplastic resin, or mixture of thermoplastic resin and thermosetting resin, and reinforcing fibers are layered, and the layered body is heated and pressurized, or is heated and then cooled under a pressurized condition to form a cured fiber-reinforced resin.

A prepreg containing an uncured thermosetting resin or thermoplastic resin, or mixture of thermoplastic resin and thermosetting resin, and reinforcing fibers can be manufactured by a known method, for example, by impregnating a reinforcing fiber bundle in which reinforcing fibers are arranged in one direction, or a woven fabric of reinforcing fibers, with an uncured thermosetting resin or thermoplastic resin, or mixture of thermoplastic resin and thermosetting resin. Further, as such a prepreg, a commercially available one may be used.

Although the molding method for molding the plate-like component is not particularly limited, from the viewpoint of mass production, press molding is preferred in which uncured materials are layered and then pressurized with a press machine to obtain the plate-like component.

### Thermoplastic Resin Component

In the member for an electronic device housing, the thermoplastic resin component comprises reinforcing fibers A and a thermoplastic resin D.

### Reinforcing Fibers A

As the reinforcing fibers A, exemplified are glass fibers, carbon fibers, aramid fibers, metal fibers, and the like, and they can be selected appropriately according to the desired purpose. Among them, glass fibers and carbon fibers are preferred from the viewpoint of good mechanical properties of injection molded articles. Further, carbon fibers are more preferable from the viewpoint of good impact resistance and good electromagnetic wave shielding property due to being provided with electrical conductivity.

The average single fiber diameter of the reinforcing fibers A is preferably 4.0 to 30 μm, more preferably 4.2 to 25 μm, and further preferably 4.5 to 20 μm. When the average single fiber diameter is 4.0 μm or more, the labor required to obtain the desired content of the reinforcing fibers is saved, and the pellets can be easily produced. When the average single fiber diameter is 30 μm or less, impregnation with the thermoplastic resin is facilitated, and dispersibility during injection molding is improved, which tends to improve the property of filling to details.

The filling to details indicates that the reinforcing fibers A and the thermoplastic resin reach the detailed portions of small spaces provided in a mold, etc. If the property of filling to details is poor, there is a possibility that a space having a length of 2 mm or less in at least one direction, such as the rib 7 shown in FIG. 4, may not be filled with the reinforcing fibers A and may end up with only the thermoplastic resin, or that both the thermoplastic resin and the reinforcing fibers A may not be filled, resulting in an insufficient shape of the rib.

The reinforcing fibers A may include a plurality of reinforcing fibers having different average single fiber diameters depending upon the purpose. The reinforcing fibers A may include three or more kinds of reinforcing fibers, but in the member for an electronic device housing, it is preferred that the reinforcing fibers A of the thermoplastic resin component contain two kinds of reinforcing fibers of reinforcing fibers B and reinforcing fibers C, each having an average fiber diameter of single fibers of 4.0 to 30.0 μm, and having average fiber diameters of single fibers different from each other, and that the reinforcing fibers B do not form a convergence part E, at least a part of the reinforcing fibers C are dispersed as single fibers, and at least another part of the reinforcing fibers C form the convergence part E. By setting the reinforcing fibers C at a material having a higher flowability than the reinforcing fibers B, it becomes possible to improve the property of filling to details while maintaining the impact resistance of the obtained molded article.

In the member for an electronic device housing, it is preferred that a mass ratio B/C of the reinforcing fibers B to the reinforcing fibers C is 99/1 to 40/60. The mass ratio B/C is more preferably 99/1 to 50/50, and further preferably 99/1 to 60/40. When the mass ratio B/C is 40/60 or more, that is, when the content of the reinforcing fibers B is 40% by mass or more in the total of 100% by mass of the reinforcing fibers B and the reinforcing fibers C, the impact resistance of the obtained molded article is likely to be improved. Further, when the mass ratio B/C is 99/1 or less, that is, when the content of the reinforcing fibers C is 1% by mass or more, the flowability during molding is improved and the property of filling to details is likely to be improved, that are preferred.

From the viewpoint of obtaining a high strength, the reinforcing fibers A preferably have a tensile strength of 3,000 MPa or more, more preferably 3,250 MPa or more, and further preferably 3,500 MPa or more.

From the viewpoint of obtaining a high elastic modulus, the reinforcing fibers A preferably have a tensile elastic modulus of 200 GPa or more, more preferably 225 GPa or more, and further preferably 400 GPa or more.

In the member for an electronic device housing, the content of the reinforcing fibers A in 100% by mass of the thermoplastic resin component is preferably 1 to 50% by mass. The content of the reinforcing fibers A is more preferably 1 to 45% by mass, and further preferably 1 to 40% by mass. When the content of the reinforcing fibers A is 1% by mass or more, the physical properties of a molded article obtained by the reinforcing fibers are likely to be improved. When the content is 50% by mass or less, the flowability during molding is improved, and the property of filling to details is likely to be improved.

### Thermoplastic Resin D

In the member for an electronic device housing, the thermoplastic resin D is not particularly limited, and for example, exemplified are polyethylene resin, polypropylene resin, polyvinyl chloride resin, polyvinylidene chloride resin, ABS resin, polystyrene resin, acrylonitrile styrene (AS) resin, methacrylic resin, polyvinyl alcohol resin, ethylene-vinyl acetate copolymer (EVA) resin, cellulose-based resin, polyamide resin, polyacetal resin, polycarbonate resin, modified polyphenylene ether resin, thermoplastic polyester resin, polytetrafluoroethylene resin, fluorine-based resin, polyphenylene sulfide resin, polysulfone resin, amorphous polyarylate resin, polyetherimide resin, polyethersulfone resin, polyetherketone resin, liquid crystal polyester resin, polyamideimide resin, polyimide resin, polyanyl ether nitrile resin, polybenzimidazole resin, etc. Among them, from the viewpoint of good mechanical properties of injection molded articles, preferred are polyethylene resin, polypropylene resin, ABS resin, polystyrene resin, AS resin, polyamide resin, polyacetal resin, polycarbonate resin, modified polyphenylene ether resin, thermoplastic polyester resin and polyphenylene sulfide resin, and polyamide resin, polycarbonate resin and ABS resin are more preferred. These thermoplastic resins may be used alone or in the form of a mixture or copolymer. In a mixture, a compatibilizer may be used in combination.

The thermoplastic resin D may contain additives such as a flame retardant, and can be used appropriately according to a desired purpose.

### Method for Manufacturing Thermoplastic Resin Component

As an example of a method for manufacturing the thermoplastic resin component, exemplified is a method using a molding material mixture containing fiber-reinforced thermoplastic resin pellets F comprising the reinforcing fibers A and the thermoplastic resin D, and fiber bundle-reinforced thermoplastic resin pellets G comprising the reinforcing fibers A and the thermoplastic resin D and containing a specific reinforcing fiber bundle I.

Although the form of the fiber-reinforced thermoplastic resin pellets F is not particularly limited, it is preferred that the pellets are formed by arranging the thermoplastic resin D so as to cover the periphery of the reinforcing fiber A. As a means for obtaining such pellets, for example, a method is exemplified in which a bundle of the reinforcing fibers A is passed through a coating die for covering an electric wire attached to the tip of an extruder, and the thermoplastic resin D is extruded and covered to obtain an electric wire-shaped gut. By cutting this gut to a predetermined length with a strand cutter, fiber-reinforced thermoplastic resin pellets F in which the length of the reinforcing fibers is substantially the same as the length of the pellets can be obtained.

The shape of the fiber-reinforced thermoplastic resin pellets F is not particularly limited, but is preferably a columnar shape with a diameter of 1 to 5 mm and a pellet length of 1 to 15 mm. When the diameter is 1 mm or more, the production is facilitated. Further, when the diameter is 5 mm or less, the pellets are easily caught into a molding machine during injection molding and the feeding thereof is facilitated. Since the pellet length is also the length of the reinforcing fibers, when the pellet length is 1 mm or more, the characteristics are easily obtained. Furthermore, when the pellet length is 15 mm or less, the feeding to a molding machine is facilitated.

In the fiber-reinforced thermoplastic resin pellets F, a resin J different from the thermoplastic resin D may be attached to the surfaces of single fibers of the reinforcing fibers A, because the dispersion effect of the reinforcing fibers A in the thermoplastic resin D during molding is likely to be improved. The resin J preferably has a melt viscosity lower than that of the thermoplastic resin D. By the condition where the melt viscosity is lower than that of the thermoplastic resin D, the resin J has a high flowability when molding the thermoplastic resin component, and the dispersion effect of the reinforcing fibers A into the thermoplastic resin D can be further improved.

The resin J is preferably a resin selected from the group consisting of an epoxy resin, a phenolic resin, a terpene resin, and a cyclic polyphenylene sulfide.

The attachment amount of the resin J is preferably 0.1 to 20 parts by mass, and more preferably 3 to 10 parts by mass, with respect to 100 parts by mass of the fiber-reinforced thermoplastic resin pellets F. By setting at such a range, it becomes easier to obtain a molding material that is excellent in moldability and handleability.

The extruder used to manufacture the fiber-reinforced thermoplastic resin pellets F is not particularly limited, and may be either a single screw type or a twin screw type. Further, the screw shape of the extruder may be a widely used full flight or double flight type, or further, may be one equipped with a high dispersion sub-flight such as Dulmage or Madoc.

The shape of the fiber bundle-reinforced thermoplastic resin pellets G is not particularly limited, but a columnar shape with a diameter of 1 to 5 mm and a pellet length of 1 to 15 mm is preferred. When the diameter is 1 mm or more, the production is facilitated. Further, when the diameter is 5 mm or less, the pellets are easily caught into a molding machine during injection molding and the feeding thereof is facilitated.

With respect to a reinforcing fiber bundle I used in the fiber bundle-reinforced thermoplastic resin pellet G, the method for forming the bundle is not limited as long as at least a part of the bundle is not dispersed as single fibers and exists in a shape of a convergence part E formed with a plurality of single fibers after integral molding with the plate-like component. The reinforcing fiber bundle I may be a fiber-reinforced plastic piece obtained by crushing a fiber-reinforced plastic comprising a thermoplastic resin having a melting point sufficiently higher than that of the injected resin, or a thermosetting resin, or a fiber-reinforced plastic piece crushed, classified, and heat-treated for recycling. From the viewpoint of reducing waste to be landfilled, it is preferred that it is a recycled fiber-reinforced plastic obtained by crushing, classifying, and heat-treating a waste fiber-reinforced plastic used with a thermosetting resin. From the viewpoint of having good properties as physical properties of the reinforcing fiber bundle, it is preferred that the recycled fiber-reinforced plastic is a CFRP (carbon fiber-reinforced plastic) using carbon fibers.

As the method for obtaining a recycled fiber-reinforced plastic, a known production method is exemplified.

For example, exemplified is a method for obtaining a recycled fiber-reinforced plastic by carrying out steps (a) through (g).
(a) a crushing step for crushing a fiber-reinforced plastic waste to manufacture fiber-reinforced plastic crushed pieces having a predetermined fiber length;
(b) a transport and storage step for transporting and storing the fiber-reinforced plastic crushed pieces in a hopper;
(c) a powder removing step for supplying the fiber-reinforced plastic crushed pieces at a fixed amount from the hopper to a powder removing device, and removing the powder contained in the fiber-reinforced plastic crushed pieces by the powder removing device to generate powder-removed fiber-reinforced plastic pieces;
(d) a pyrolysis step for heating the powder-removed fiber-reinforced plastic pieces while supplying them at a fixed amount to a pyrolysis furnace and removing the matrix resin component contained in the powder-removed fiber-reinforced plastic pieces to obtain a recycled reinforcing fiber pyrolysis product;
(e) a cooling and transporting step for cooling the recycled reinforcing fiber pyrolysis product and sending it to a next process;
(f) a classification step for classifying the recycled reinforcing fiber pyrolysis product to obtain a recycled reinforcing fiber classified product; and
(g) an iron removing step for removing metal powder from the recycled reinforcing fiber classified product by magnetic force.

The method of the crushing step is not particularly limited, but it is preferable to use two or more crushers for efficient crushing. In one example of using two or more crushers, the fiber-reinforced plastic waste, which is a raw material, is first put into a primary crusher and roughly crushed, and then transported to secondary and subsequent crushers for crushing. It is preferred to crush the waste in the final crusher until it becomes smaller than a mesh size of a screen set to a desired size.

The transport method in the transport and storage step is not particularly limited, but it is preferred to transport the powder generated by crushing in the crushing step, which is derived from the fiber-reinforced plastic crushed pieces and the fiber-reinforced plastic waste, by an air-blowing system, a belt conveyor system, a bucket conveyor system, etc., and store it in a hopper. Among these, it is more preferable to transport by an air-blowing system because the equipment cost is low.

The method for the powder removing step is not particularly limited, but it is preferred to separate the fiber-reinforced plastic crushed pieces to be sent to the next process from the powder, using a vibrating sieve.

As the heating system for the pyrolysis furnace in the pyrolysis step, electric heaters, hot air, etc. are exemplified, but in handling conductive reinforcing fibers such as carbon fibers, the hot air system is preferred. As the material transport system in the pyrolysis furnace, there are a belt conveyor system, a bucket conveyor system, further, a rotary kiln system in which the pyrolysis furnace itself rotates, etc. Since the inside of the pyrolysis furnace is at a high temperature, the rotary kiln system, which does not use a conveyor, is preferred from the viewpoint of equipment life.

The heat treatment temperature in an air atmosphere in the heat treatment step is preferably 300° C. to 700° C. When the heat treatment temperature in an air atmosphere is 700° C. or lower, resin H described later tends to remain, and the reinforcing fibers and the resin H tend to coexist. As a result, the convergence property of the reinforcing fiber bundle I is improved, and the reinforcing fiber bundle I tends to remain as the convergence part E after integration molding, which tends to improve the mechanical properties and dimensional accuracy. Further, when the heat treatment temperature in an air atmosphere is 300° C. or higher, the resin H is reduced, the toughness as a matrix resin tends to be improved, and the mechanical properties tend to be improved.

The conveying system in the cooling and conveying step is not particularly limited, and there may be a thermal resistance sufficient to convey the recycled reinforcing fiber pyrolysis product in a high temperature state immediately after pyrolysis. The cooling system is also not particularly limited, and exemplified are air cooling, natural cooling, etc. Among them, natural cooling is preferred because no cooling equipment is required. Further, it is also preferred to use a belt conveyor system, a bucket conveyor system or the like as the conveying system and employ natural cooling during conveying.

The classification method in the classification step is not particularly limited, but a vibrating sieve is preferred because a recycled reinforcing fiber classified product of a desired size can be obtained by changing the number of stages and the screen mesh.

The iron removing method in the iron removing step is not limited, but it is preferred to install a device that removes metal powder by magnetic force in a pipe through which the reinforcing fiber classified product passes, thereby recovering iron powder generated during the process, or to separate the iron powder by using the difference in falling behavior due to the presence or absence of magnetism when being passed near a magnet. In consideration of processability, the long side of the obtained recycled fiber-reinforced plastic is preferably 1 to 20 mm, more preferably 3 to 14 mm, and further preferably 5 to 8 mm. A sizing agent may be provided since this tends to improve handleability.

As another method for obtaining recycled fiber-reinforced plastics, a method can also be exemplified for cutting the fiber-reinforced plastic to a desired size after heating it without crushing it. The heating is preferably performed in an oxygen-free atmosphere. For the heating, a heat treatment furnace also is preferably used, which has a box-shaped main body, a heat treatment chamber arranged inside the main body to store the fiber-reinforced plastic, a combustion chamber arranged at the bottom of the heat treatment chamber and equipped with a burner, and a heating chamber formed in the space between the main body and the heat treatment chamber, and in which the fiber-reinforced plastic is heat-treated in the heat treatment chamber to convert a part of the matrix component contained in the fiber-reinforced plastic and adhere it to the surface of the reinforcing fibers as a resin H described later. The heat treatment temperature in the oxygen-free atmosphere in the heat treatment chamber is preferably 200° C. to 800° C. Further, the heat treatment furnace is equipped with a steam generator, and by supplying steam at 100° C. or more and 700° C. or less to the heat treatment chamber, convection in the heat treatment chamber is promoted, and the gas of the matrix component generated in the heat treatment chamber can be efficiently expelled. It is possible to prevent deposition on the floor or wall of the heat treatment chamber and generation of tar in the piping due to the matrix component remaining in the heat treatment chamber. It is not preferred to supply steam heated to a temperature exceeding 700° C. because it applies a load on the heat treatment chamber and the piping. The obtained recycled reinforcing fibers are cut to a desired length by a known method such as a rotary cutter. In consideration of processability, the long side is preferably 1 to 20 mm, more preferably 3 to 14 mm, and further preferably 5 to 8 mm. A sizing agent may be provided because it is easy to improve the handleability.

The obtained recycled reinforcing fibers also are preferably subjected to iron removal treatment depending upon the purpose.

Furthermore, in another method for obtaining recycled fiber-reinforced plastics, waste pieces crushed and classified with fiber-reinforced plastic molded products are spread evenly on a metal bat, put in an electric muffle furnace, and heat treated while introducing nitrogen gas into the furnace and maintaining the treatment temperature at a specified temperature. Thereafter, similarly, heat treatment is performed while introducing air into the furnace and maintaining the treatment temperature at a specified temperature to obtain recycled fiber-reinforced plastics.

The heat treatment temperature in an air atmosphere in the heat treatment step is preferably 300° C. to 700° C. When the heat treatment temperature in an air atmosphere is 700° C. or lower, a resin H described later tends to remain, and the reinforcing fibers and the resin H tend to coexist. As a result, the convergence property of the reinforcing fiber bundle I is improved, and it tends to remain as a convergence part E after integral molding, which tends to improve the mechanical properties and dimensional accuracy. Further, when the heat treatment temperature in an air atmosphere is 300° C. or higher, the resin H is reduced, the toughness as a matrix resin tends to be improved, and the mechanical properties tend to be improved.

Further, some examples carry out the final heat treatment in an air atmosphere. In an inert nitrogen gas atmosphere, the resin H is unlikely to change even if the heat treatment is carried out for a long time, but by carrying out the final heat treatment in an active air atmosphere, it becomes easier to obtain a recycled fiber-reinforced plastic having the desired resin H.

As crushers for fiber-reinforced plastic, exemplified are shear crushers, impact crushers, cutting crushers, compression crushers etc. There is no problem with using any crusher, and they can be combined. Further, as classifiers for crushed products, exemplified are vibration sieves, gyroscopic sieves, centrifugal sieves and the like. In some instances, it is useful in matching the crushing capacity of the crusher and the form of the crushed material.

The long side of the crushed recycled fiber-reinforced plastic is preferably 1 to 20 mm, more preferably 3 to 14 mm, and further preferably 5 to 8 mm.

### Molding Material Mixture

As long as the fiber-reinforced thermoplastic resin pellets F, the fiber bundle-reinforced thermoplastic resin pellets G, and the thermoplastic resin D can be mixed at a predetermined ratio according to the purpose, the method thereof is not particularly limited, and the molding material mixture may be prepared by a method such as melt kneading or dry blending. Among them, dry blending is preferable because the content of the reinforcing fibers in the molded article can be easily adjusted. Differently from melt kneading, the dry blending indicates to stir and mix a plurality of materials at a temperature at which the resin components do not melt, and make the mixture substantially uniform, and it is preferably used when a pellet-shaped molding material is used, mainly such as in injection molding or extrusion molding. Thermoplastic resin pellets that do not have reinforcing fibers may be mixed to achieve the desired fiber content, and additives such as flame retardants may be added according to the purpose.

### Member for an Electronic Device Housing

The member for an electronic device housing has a thermoplastic resin component integrated with at least a part of the peripheral edge region of the plate-like component. “Integration” indicates to melt the thermoplastic resin component, the plate-like component, or both, and then cool and bond them. The peripheral edge region is the outer circumference part of the plate-like component, but it is also preferable to integrate the thermoplastic resin component so that a part thereof overlaps the plate-like component to increase the adhesive strength with the thermoplastic resin component.

In the member for an electronic device housing, in the thermoplastic resin component, a part of the reinforcing fibers A are dispersed as single fibers, and another part of the reinforcing fibers A are not dispersed as single fibers but are arranged randomly in a shape of a convergence part E formed from a plurality of single fibers. The number of single fibers forming the convergence part E is preferably 2 or more, more preferably 5 or more, and further preferably 10 or more. Although the upper limit of the number of single fibers forming the convergence part E is not particularly limited, it is preferably 100,000 or less, more preferably 80,000 or less, and further preferably 60,000 or less. When the number of single fibers forming the convergence part E is 2 or more, the impact resistance when the obtained molded article is dropped can be improved. Further, when the number of single fibers forming the convergence part E is 100,000 or less, the flowability during integral molding is improved and the property for filling to details is easily improved.

The length of the long side of the convergence part E is preferably 0.5 to 20 mm, more preferably 0.8 to 15 mm, and further preferably 1.0 to 10 mm. When the length of the long side of the convergence part E is 0.5 mm or more, the physical properties of the molded article tend to be improved. When the length of the long side of the convergence part E is 20 mm or less, the flowability during integral molding is improved, and the property for filling to details tends to be improved.

The length of the long side of the convergence part E indicates a length of the longest single fiber among the single fibers forming the convergence part E. The convergence part E may contain a single fiber shorter than 0.5 mm.

The convergence parts E exist randomly means that the convergence parts E are not aligned in a specific orientation. The acute angle side of the angles formed by the long side of the convergence part E and the long side of another convergence part E that is not in contact with the convergence part E is preferably 20° or more, more preferably 25° or more, and further preferably 30° or more. The angle of the convergence part E can be measured by observing a cross section cut at a desired position of the thermoplastic resin component with an optical microscope. Among the angles formed by the lines extending from the long sides of the observable convergence part E and another convergence part E that is not in contact, it is preferred that at least one angle is 20° or more.

The reinforcing fibers A contained in the thermoplastic resin component are preferably discontinuous reinforcing fibers. The discontinuous reinforcing fibers indicate fibers that are not continuous in one direction at a length of 100 mm or more, and a large number of such fibers are arranged in different directions.

When a thermoplastic resin component is injection molded, because the reinforcing fibers become shorter during the injection molding process, the average fiber length of the reinforcing fibers in the molded article becomes usually shorter than the average fiber length at the pellet stage, which is the molding material. If the average fiber length of the reinforcing fibers in the molded article is too short, the impact resistance decreases, and if it is too long, it becomes necessary to lengthen the average fiber length at the molding material stage before the injection molding, and if the average fiber length at the molding material stage is too long, the property for filling to details becomes insufficient. From this viewpoint, the average fiber length of the reinforcing fibers A in the molded product is preferably 10 μm to 20 mm, more preferably 12 μm to 15 mm, and further preferably 15 μm to 10 mm. When the average fiber length of the reinforcing fibers A is 10 μm or more, the physical properties of the molded article are likely to be improved. Further, when the average fiber length of the reinforcing fibers A is 20 mm or less, the flowability during integral molding is improved, and the property for filling to details is likely to be improved.

In the member for an electronic device housing, the convergence part E means a part which is integrated by the resin H different from the thermoplastic resin D attached to the surfaces of the constituent single fibers and in which the direction of the fibers is aligned without being dispersed. “The fiber direction is aligned” indicates a state where most of the single fibers forming the convergence part E are oriented in the same direction. The angular deviation between the single fibers forming the convergence part E is preferably 20° or less, more preferably 10° or less, and further preferably 5° or less. If the angular deviation between the single fibers forming the convergence part E is 20° or less, the physical properties of the molded article are likely to be improved. The angle between the single fibers indicates an angle between the lines obtained by observing the convergence part E with a microscope or the like, selecting any two of the single fibers forming the convergence part E, and drawing a line along the longitudinal direction of each single fiber.

The resin H is attached preferably at an amount of 0.1 to 30 parts by mass, more preferably 3 to 20 parts by mass, and further preferably 5 to 15 parts by mass, with respect to 100 parts by mass of the reinforcing fibers A contained in the convergence part E. When the content of the resin His 0.1 part by mass or more, because the convergence property is improved and the convergence part E is easily formed, the mechanical properties are easily improved. When the content of the resin H is 30 parts by mass or less, the dispersibility of the reinforcing fibers is improved, the flowability during integral molding is improved, the property for filling to details is easily improved, and in addition, the appearance of the obtained molded article is likely to be improved.

The resin H is not particularly limited as long as it can bond the single fibers of the reinforcing fibers together to form the convergence part E, and is different from the resin J which does not have such a function, and as examples thereof, exemplified are a thermoplastic resin having a melting point sufficiently higher than the melting point of the surrounding thermoplastic resin D which is an injected resin, a thermosetting resin, a thermosetting resin which has been heat-treated as a recycled resin, and the like.

As examples of the thermoplastic resin, the thermoplastic resin D, and the like. As examples of the thermosetting resin, exemplified are those exemplified as one for the plate-like component, and the like.

The resin H can be confirmed as a layer different from the surrounding resin D when a cross section formed by cutting the thermoplastic resin component is observed by an optical microscope or the like. The resin H can be determined by using the difference between the thermoplastic resin D and the resin H with respect to the melting point and the solubility in a solvent. As an example of the determination method, an instance is shown where the reinforcing fibers A forming the convergence part E are recycled fiber-reinforced plastics obtained by extracting CFRP comprising epoxy resin and carbon fibers by any of the above-described heat treatments, and the thermoplastic resin D is polycarbonate resin, but the determination method is not limited as long as the resin H can be determined after the convergence part E is taken out from the thermoplastic resin D. A polycarbonate piece to be determined is taken out from the molded article, placed in THF (tetrahydrofuran), and left for 24 hours. The convergence part E comprising two or more carbon fibers separated from the polycarbonate is taken out with tweezers, sufficiently dried, and then the weight K before heating is measured. The convergence part E whose weight has been measured is placed in an electric furnace into which nitrogen is sucked and exhausted, heated at 600° C. for 3.5 hours in a nitrogen atmosphere to burn off the thermoplastic resin H, and then cooled to a room temperature. Thereafter, the weight is measured again, and the weight after heating L is measured. The weight of thermoplastic resin H=the weight before heating K−the weight after heating L. The method for determining the thermoplastic resin H is also preferably performed using a thermogravimetry-differential thermal analyzer (TG-DTA) or by the method described in JIS K7075, depending upon the amount of the sample obtained.

Although the method for producing the member for an electronic device housing is not particularly limited, for example, exemplified are (i) a method in which a plate-like component and a thermoplastic resin component are separately molded in advance and then bonded to each other; (ii) a method in which a plate-like component is molded in advance, and a thermoplastic resin component is molded and joined to each other at the same time; etc.

As a concrete example of (i), exemplified are a method in which a plate-like component is press-molded, and a thermoplastic resin component is press-molded or injection-molded, and the respective components thus manufactured are joined by a known welding means such as hot plate welding, vibration welding, ultrasonic welding, laser welding, resistance welding, or induction heating welding, and the like.

On the other hand, as a concrete example of (ii), exemplified are a method in which a plate-like component obtained by press molding is placed in an injection molding die, a material for forming a thermoplastic resin component is insert injection molded or outsert injection molded into the die, and the thermoplastic resin component, which is a molded body obtained by injection molding, is joined to the plate-like component, and the like.

From the viewpoint of mass production of the integrally molded article, the method (ii) is preferable. In the injection molding of the thermoplastic resin component, the desired shape may be obtained in one molding, or the injection molding may be performed in multiple steps. However, to reduce the amount of deformation due to curing shrinkage after molding, it is preferred to perform the injection molding in multiple steps.

As an example, a method for producing a member for an electronic device housing by integrating a plate-like component and a thermoplastic resin component by injection molding will be shown below. However, within the scope of our member, the integration method can be selected according to the purpose and is not particularly limited.

The plate-like component is set in an injection mold, the mold is closed, and then the molding material mixture prepared above is injection molded onto the periphery part of the plate-like component to form a member for an electronic device housing having an integrated thermoplastic resin component. The plate-like component may be processed into a predetermined shape and size before being set in the injection mold.

### EXAMPLES

Next, our member will be explained with reference to examples, but is not limited to these examples.

First, the methods for evaluating the weight average fiber length and average single fiber diameter used in these examples will be explained.
(1) Weight average fiber length (hereinafter, may be simply referred to as average fiber length)

A test piece cut out from a molded article was put into a solvent in which the thermoplastic resin D and the resin H used in each Example and Comparative Example were dissolved, and a heat treatment was appropriately applied to obtain a solution in which the reinforcing fibers A were uniformly dispersed. Thereafter, the solution was filtered using a quantitative filter paper (No. 5C) supplied by Advantec Co., Ltd., and the reinforcing fibers A dispersed on the filter paper were observed by an optical microscope (50 to 200 times). The fiber lengths of 1,000 randomly selected reinforcing fibers A were measured, and the weight average fiber length (Lw) was calculated from the equation.

$$Average fiber length = \sum ( {Mi}^{2} \times Ni ) / \sum ( Mi \times Ni )$$

Mi: fiber length (mm)
Ni: number of fibers with fiber length Mi
(2) Average single fiber diameter (hereinafter, may be simply referred to as single fiber diameter)

A test piece cut out from a molded article was put into a solvent in which the thermoplastic resin D and the resin H used in each Example and Comparative Example were dissolved, and a heat treatment was appropriately applied to obtain a solution in which the reinforcing fibers A were uniformly dispersed. Thereafter, the solution was filtered using a quantitative filter paper (No. 5C) supplied by Advantec Co., Ltd., and the reinforcing fibers A dispersed on the filter paper were observed by an optical microscope (50 to 200 times). The single fiber diameters of 1,000 randomly selected reinforcing fibers A were measured, and the average single fiber diameter was calculated from the equation.

$$Average single fiber diameter = \sum ( Di ) / Ni$$

Di: single fiber diameter (μm)
Ni: number of fibers with single fiber diameter Di

### Example 1

### Method of Molding Plate-Like Component

Five layers of carbon fiber unidirectional prepreg (“TORAYCA” (registered trademark) prepreg) P3052S-15 (carbon fiber: T700SC-24K, epoxy resin 33% by mass was contained in 100% by mass of the entire prepreg, average single fiber diameter: 7.0 μm) supplied by Toray Industries, Inc. were layered. The layering configuration of the prepreg was such that, when the longitudinal direction of the fiber-reinforced plastic molded article was 0°, the carbon fiber orientations were 0°/90°/0°/90°/0° from the outermost layer. This layered body was sandwiched between release films and it was press molded (mold temperature: 150° C., pressure: 1.5 MPa, curing time: 30 minutes, target thickness after pressing: 0.7 mm) to obtain a plate-like component.

### Fiber-Reinforced Thermoplastic Resin Pellet F

As the reinforcing fibers A, carbon fibers supplied by Toray Industries, Inc. (“TORAYCA” (registered trademark) T700SC-24K, average single fiber diameter: 7.0 μm) were used.

A fiber-reinforced resin pellet manufacturing apparatus having a coating die for a wire resin coating method installed at the tip of a TEX-30α type twin-screw extruder (screw diameter: 30 mm, L/D=32) supplied by Japan Steel Works, Ltd. was used, the extruder cylinder temperature was set at 230° C., and a polycarbonate resin (Teijin Chemical Co., Ltd., “Panlite” (registered trademark) L-1225L) was supplied as the thermoplastic resin D from a main hopper and melt-kneaded at a screw rotational speed of 200 rpm. The discharge amount of an epoxy resin (supplied by Japan Epoxy Resins Co., Ltd., “jER828”) heated and melted at 250° C. was adjusted to 6 parts by mass with respect to 100 parts by mass of the total of the reinforcing fibers A and the thermoplastic resin D. Thereafter, the epoxy resin was discharged and impregnated into a fiber bundle comprising the reinforcing fibers A, and the fiber bundle of the reinforcing fibers A to which the epoxy resin was provided was then supplied to a die port (diameter: 3 mm) for discharging molten polycarbonate resin, and the fiber bundle was continuously arranged so that the circumferences of the reinforcing fibers A were covered with the thermoplastic resin D. At this time, in the internal cross section of the fiber bundle, at least a part of the reinforcing fibers A were in contact with the thermoplastic resin D. After cooling the obtained strand, it was cut with a cutter to a pellet length of 7 mm to obtain a fiber-reinforced thermoplastic resin pellet F. At this time, the take-up speed was adjusted so that the amount of the reinforcing fibers A became 30 parts by mass with respect to the total of 100 parts by mass of the reinforcing fibers A and the thermoplastic resin D. The length of the reinforcing fibers A of the obtained fiber-reinforced thermoplastic resin pellet F was substantially the same as the pellet length, and the reinforcing fiber bundle was aligned parallel to the axial direction of the molding material.

### Fiber Bundle-Reinforced Thermoplastic Resin Pellet G

A unidirectional carbon fiber prepreg (“TORAYCA” (registered trademark) prepreg) P3052S-15 (carbon fiber: T700SC-24K, 33% by mass of epoxy resin was contained in 100% by mass of the entire prepreg, average single fiber diameter: 7.0 μm) supplied by Toray Industries, Inc. was cured at 180° C. for 2 hours to obtain a CFRP. Thereafter, 200 g of the CFRP pieces, which had been crushed and classified so that the number average long side size was 5 to 8 mm, were uniformly spread on a metal bat and placed in an electric muffle furnace with an internal volume of 59 liters, and heat-treated for 5 hours while maintaining the treatment temperature at a predetermined temperature (550° C.) in an oxidizing atmosphere to obtain a recycled carbon fiber bundle. A part of the original resin was attached to the surface of the recycled carbon fiber bundle, and formed was a fiber bundle I with an average fiber length of 8 mm.

Next, a polycarbonate resin “Panlite” (registered trademark) L-1225L, supplied by Teijin Chemical Co., Ltd., was supplied as the thermoplastic resin D to a main hopper of a twin-screw extruder (TEX30α, supplied by Japan Steel Works, Ltd.), and the reinforcing fiber bundle I obtained above was fed from a side feeder into the molten resin, and the screw rotational speed was set at 200 rpm. The strand discharged from the die was cooled in water, cut to a length of 3.0 mm with a strand cutter and pelletized to obtain fiber the fiber bundle-reinforced thermoplastic resin pellet G. At this time, the amount of the reinforcing fiber bundle I was adjusted so that the amount of the reinforcing fiber bundle I became 30 parts by mass with respect to the total of 100 parts by mass of the thermoplastic resin D and the reinforcing fiber bundle I.

### Molding Material Mixture

The fiber-reinforced thermoplastic resin pellets F and the fiber bundle-reinforced thermoplastic resin pellets G thus obtained were dry blended so that the mass ratio of the reinforcing fibers A contained in the fiber-reinforced thermoplastic resin pellets F to the reinforcing fibers A contained in the fiber bundle-reinforced thermoplastic resin pellets G was 70/30, to obtain a molding material mixture as an intermediate raw material.

Integral Molding with Thermoplastic Resin Component

The molded plate-like component was processed to a size of 318 mm×211 mm, set in an injection molding die, the die was closed, and then produced was a composite molded article by injection molding the molding material mixture onto the peripheral part of the plate-like component as a thermoplastic resin component.

The injection mold used had a shape that would form a rib with a width of 1 mm and a height of 5 mm on the completed molded article, and the thermoplastic resin component was filled in every detail. The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., it was found that the reinforcing fibers A were dispersed as single fibers throughout the thermoplastic resin component, and a part thereof existed as convergence parts E each having two or more single fibers.

Thereafter, for the evaluation of impact resistance, a weight of 1 kg was attached to the composite molded article obtained above, and the article was dropped from a height of 700 mm so that a corner of the integrated thermoplastic resin component hit the ground first, but no cracks occurred. The average fiber length of the reinforcing fibers A contained in the obtained thermoplastic resin component was 0.3 mm.

### Example 2

Carbon fiber prepreg (“TORAYCA” (registered trademark) prepreg) P2352W-19 (carbon fiber: T800SC-24K, 35% by mass of epoxy resin was contained in 100% by mass of the entire prepreg, fiber diameter: 5.5 μm) supplied by Toray Industries, Inc. was cured at 180° C. for 2 hours to obtain CFRP. Thereafter, 200 g of the CFRP pieces, which had been crushed and classified so that the number average length of the long sides was 5 to 8 mm, were uniformly spread on a metal bat and placed in an electric muffle furnace with an internal volume of 59 liters, and heat-treated for 5 hours while maintaining the treatment temperature at a predetermined temperature (550° C.) in an oxidizing atmosphere to obtain a recycled carbon fiber bundle. A part of the original resin was attached to the surface of the recycled carbon fiber bundle, and the fiber bundle I with an average fiber length of 8 mm was formed. A composite molded article was produced in the same manner as in Example 1, other than conditions where the fiber bundle-reinforced thermoplastic resin pellets G were produced using this fiber bundle I and used as an injection molding material.

The thermoplastic resin component of the composite molded article obtained above was in a state filled to details. To evaluate impact resistance, a weight of 1 kg was attached to the composite molded article and it was dropped from a height of 700 mm so that a corner of the integrated thermoplastic resin component hit the ground first, but no cracks occurred.

The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., it was found that the reinforcing fibers A were dispersed as single fibers throughout the thermoplastic resin component, and a part thereof existed as convergence parts E each having two or more single fibers. The average fiber length of the reinforcing fibers A contained in the obtained thermoplastic resin component was 0.5 mm.

### Example 3

A composite molded article was produced in the same manner as in Example 1, other than conditions where when the fiber-reinforced thermoplastic resin pellets F and the fiber bundle-reinforced thermoplastic resin pellets G were dry blended to prepare a molding material mixture as an intermediate raw material, resin pellets comprising the thermoplastic resin D not containing reinforcing fibers A were added so that the content of the reinforcing fibers became 10 mass % in 100 mass % of the entire molding material mixture.

The thermoplastic resin component of the composite molded article obtained above was in a state filled to details. To evaluate impact resistance, a weight of 1 kg was attached to the composite molded article and it was dropped from a height of 700 mm so that a corner of the integrated thermoplastic resin component hit the ground first, but no cracks occurred.

The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., it was found that the reinforcing fibers A were dispersed as single fibers throughout the thermoplastic resin component, and a part thereof existed as convergence parts E each having two or more single fibers. The average fiber length of the reinforcing fibers A contained in the obtained thermoplastic resin component was 0.3 mm.

### Example 4

Two sheets were prepared as skin materials by layering carbon fiber unidirectional prepregs (UD PP) P3052S-15 (supplied by Toray Industries, Inc., using carbon fiber T700S, containing 33 mass % of an epoxy resin in 100 mass % of the entire prepreg, average single fiber diameter: 7 μm, thickness: 0.12 mm) by two layers so that the fiber arrangement directions were perpendicular to each other. A foam material (F-Cell (registered trademark) RC2010, supplied by Furukawa Electric Co., Ltd., double-expanded polypropylene) was prepared as a core material. The foam material was arranged as a core material, and adhesive polyolefin nonwoven fabric (supplied by Japan Vilene Co., Ltd., melting point: 150° C., areal weight: 15 g/m²) was arranged above and below the core material to bond the core material and the skin materials, and then the core material was sandwiched between the skin materials to obtain a layered body. Furthermore, a composite molded article was produced in the same manner as in Example 1, other than a condition where this layered body was press molded (mold temperature: 150° C., pressure: 6 MPa, curing time: 30 minutes, target thickness after pressing: 1.5 mm) to obtain a plate-like component. As compared with Example 1, the inclusion of a core material reduced the amount of deflection when a load was applied to the plate-like component while maintaining its light weight.

The thermoplastic resin component of the composite molded article obtained above was in a state filled to details. To evaluate impact resistance, a weight of 1 kg was attached to the composite molded article and it was dropped from a height of 700 mm so that a corner of the integrated thermoplastic resin component hit the ground first, but no cracks occurred.

The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., it was found that the reinforcing fibers A were dispersed as single fibers throughout the thermoplastic resin component, and a part thereof existed as convergence parts E each having two or more single fibers. The average fiber length of the reinforcing fibers A contained in the obtained thermoplastic resin component was 0.3 mm.

### Example 5

A polymer mainly composed of polyacrylonitrile was spun and sintered to obtain a continuous carbon fiber bundle with a total number of filaments of 12,000. A sizing agent was applied to the continuous carbon fiber bundle by a dipping method, and the bundle was dried in heated air at a temperature of 120° C. to obtain a PAN-based carbon fiber bundle. The PAN-based carbon fiber bundle was cut using a cartridge cutter to obtain a chopped carbon fiber bundle with a fiber length of 6 mm.

Further, 100L of an aqueous solution of 1.5 parts by mass of a surfactant (supplied by Wako Pure Chemical Industries, Ltd., product name “sodium n-dodecylbenzene sulfonate”) was stirred to prepare a pre-foamed dispersion. The chopped carbon fiber bundles obtained above were added to this dispersion and stirred for 10 minutes, and then the dispersion was poured into a papermaking machine having a papermaking surface of 400 mm in length and 400 mm in width, dehydrated by suction, and then dried at a temperature of 150° C. for 2 hours to obtain a carbon fiber mat.

90 parts by mass of an unmodified polypropylene resin (supplied by Prime Polymer Co., Ltd., “Prime Polypro” (registered trademark) J105G, melting point: 160° C.) and 10 parts by mass of an acid-modified polypropylene resin (supplied by Mitsui Chemicals, Inc., “Admer” (registered trademark) QE510, melting point: 160° C.) were prepared and dry-blended. This dry-blended product was charged from a hopper of a twin-screw extruder, melt-kneaded in the extruder, and then extruded from a T-shaped die having a width of 400 mm. Thereafter, it was cooled and solidified by taking it up with a chill roll at 60° C., and two thermoplastic resin films were produced.

Two sheets were prepared as skin materials by layering carbon fiber unidirectional prepregs (UD PP) P3052S-15 (supplied by Toray Industries, Inc., using carbon fiber T700S, containing 33 mass % of an epoxy resin in 100 mass % of the entire prepreg, average single fiber diameter: 7 μm, thickness: 0.12 mm) by two layers so that the fiber arrangement directions were perpendicular to each other. The obtained thermoplastic resin films were placed above and below the carbon fiber mat, and then it was sandwiched between the skin materials to obtain a layered body.

Next, the layered body was sandwiched between release films and press molded (mold temperature: 180° C., pressure: 3 MPa, heating time: 30 minutes, target thickness after pressing: 1.5 mm) to cure the skin precursor to form a skin material, and the thermoplastic resin film was softened and impregnated into the carbon fiber mat to form a core layer precursor, and the skin material and the core layer precursor were integrated. Thereafter, the mold gap was widened by 0.7 mm, and the core layer precursor was expanded by its restoring force to form a core layer having voids. Further, after 4 minutes passed, the mold was opened and it was quickly placed on the plate surface of a cooling press mold with a plate surface temperature of 40° C., and cold pressed at 3 MPa. After 5 minutes, the molded article was taken out from the press mold to obtain a sandwich structural body with a plate thickness of 1.3 mm, a skin layer thickness of 0.15 mm, and a core layer thickness of 1.0 mm. It was the same as Example 1 except that the sandwich structural body was a plate-like component. As compared with Example 1, the inclusion of a core material reduced the amount of deflection when a load was applied to the plate-like component while maintaining its light weight.

The thermoplastic resin component of the composite molded article obtained above was in a state filled to details. To evaluate impact resistance, a weight of 1 kg was attached to the composite molded article and it was dropped from a height of 700 mm so that a corner of the integrated thermoplastic resin component hit the ground first, but no cracks occurred.

The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., it was found that the reinforcing fibers A were dispersed as single fibers throughout the thermoplastic resin component, and a part thereof existed as convergence parts E each having two or more single fibers. The average fiber length of the reinforcing fibers A contained in the obtained thermoplastic resin component was 0.3 mm.

### Comparative Example 1

The same procedure as in Example 1 was employed other than a condition where the fiber-reinforced thermoplastic resin pellets G were not mixed, and only the fiber-reinforced thermoplastic resin pellets F were used.

A molding material mixture comprising only the fiber-reinforced thermoplastic resin pellets F was injection molded onto the peripheral edge part of the plate-like component in the same manner as in Example 1 to produce a composite molded article. However, there was no thermoplastic resin at the tops of the ribs, and there were some areas where the thermoplastic resin was not filled to details.

The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., it was found that the reinforcing fibers A were dispersed as single fibers throughout the thermoplastic resin component, but convergence parts E each having two or more single fibers were not observed.

Thereafter, to evaluate impact resistance, when a weight of 1 kg was attached to the composite molded article obtained above and it was dropped from a height of 700 mm so that a corner of the integrated thermoplastic resin component hit the ground first, no cracks occurred. The average fiber length of the reinforcing fibers A contained in the obtained thermoplastic resin component was 1.0 mm. Because the fiber bundle-reinforced thermoplastic resin pellets with excellent flowability were not contained, the resulted property for filling to details was decreased.

### Comparative Example 2

A carbon fiber prepreg (“TORAYCA” (registered trademark) prepreg) P3052S-15 (carbon fiber: T700SC-24K, 33% by mass of epoxy resin was contained in 100% by mass of the entire prepreg, average single fiber diameter: 7.0 μm) supplied by Toray Industries, Inc. was cured at 180° C. for 2 hours to obtain a CFRP. Thereafter, CFRP pieces, which had been crushed and classified so that the number average long side size was 5 to 8 mm, were prepared as reinforcing fiber bundle I without heat treatment. The same procedure as in Example 1 was employed other than conditions where the obtained reinforcing fiber bundle I was used to prepare the fiber bundle-reinforced thermoplastic resin pellet G, and the fiber-reinforced thermoplastic resin pellet F was not used.

Although the thermoplastic resin component of the composite molded article obtained above was filled to details, a part of it fell off when demolded. The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., it was found that the reinforcing fibers A existed as a convergence part E in which two or more single fibers were gathered, and since the CFRP was not heat-treated, a large amount of the resin H remained, and the reinforcing fibers A dispersed as single fibers were not observed. Further, many regions in which the reinforcing fibers did not exist were observed around the ribs.

Thereafter, to evaluate impact resistance, when a weight of 1 kg was attached to the composite molded article obtained above and it was dropped from a height of 700 mm so that a corner of the integrated thermoplastic resin component hit the ground first, a crack of about 50 mm was generated in the thermoplastic resin component starting from the corner, and a part of the thermoplastic resin broke and fell off.

The average fiber length of the reinforcing fibers A contained in the obtained thermoplastic resin component was 3.0 mm. As the result that the reinforcing fibers were insufficiently dispersed, resulting increase of the region where the reinforcing fibers were not present, the impact resistance decreased.

### Comparative Example 3

A polymer mainly composed of polyacrylonitrile was spun and sintered to obtain a continuous carbon fiber bundle with a total number of filaments of 12,000. A sizing agent was applied to the continuous carbon fiber bundle by a dipping method, and the bundle was dried in heated air at a temperature of 120° C. to obtain a PAN-based carbon fiber bundle. The PAN-based carbon fiber bundle was cut using a cartridge cutter to obtain the reinforcing fiber bundle I with a fiber length of 6 mm. The same procedure as in Example 1 was employed other than conditions where the obtained reinforcing fiber bundle I was used to prepare the fiber bundle-reinforced thermoplastic resin pellet G, and the fiber-reinforced thermoplastic resin pellet F was not used.

The thermoplastic resin component of the composite molded article obtained above was filled to details. The surface of the obtained thermoplastic resin component was polished with a sandpaper 33-648 (P800) supplied by Refine Tech Co., Ltd., and when the surface was observed at a magnification of 150 times using a scanning electron microscope (SEM) J SM-6010LV supplied by JEOL Ltd., the reinforcing fibers A were dispersed as single fibers, and no convergence part E in which two or more single fibers were gathered was observed.

Thereafter, to evaluate impact resistance, when a weight of 1 kg was attached to the composite molded article obtained above and it was dropped from a height of 700 mm so that a corner of the integrated thermoplastic resin component hit the ground first, a crack of about 10 mm was generated in the thermoplastic resin component starting from the corner.

The average fiber length of the reinforcing fibers A contained in the obtained thermoplastic resin component was 0.1 mm. In addition to the absence of the convergence part E having a reinforcement effect, the length of the reinforcing fibers was short, resulting in a decrease in impact resistance.

TABLE 1

| | | Fiber-reinforced | Fiber bundle-reinforced | Molded article | |
|---|---|---|---|---|---|
| | | thermoplastic resin | thermoplastic resin | Reinforcing | Content of |
| | | pellet F | pellet G | fibers contained | reinforcing |
| | | Average single | Average single | in pellet | fibers A in |
| | | fiber diameter of | fiber diameter of | F/Reinforcing | thermoplastic |
| | | reinforcing | reinforcing | fibers contained | resin |
| | Plate-like | fibers | fibers | in pellet G | component |
| | component | [μm] | [μm] | (mass ratio) | (mass %) |
| Example 1 | CFRP layered | 7 | 7 | 70/30 | 30 |
| | plate | | | | |
| Example 2 | CFRP layered | 7 | 5.5 | 70/30 | 30 |
| | plate | | | | |
| Example 3 | CFRP layered | 7 | 7 | 90/10 | 10 |
| | plate | | | | |
| Example 4 | Sandwich | 7 | 7 | 70/30 | 30 |
| | structural body | | | | |
| | (Foamed material) | | | | |
| Example 5 | Sandwich | 7 | 7 | 70/30 | 30 |
| | structural body | | | | |
| | (Carbon fiber mat) | | | | |
| Comparative | CFRP layered | 7 | — | 100/0 | 30 |
| Example 1 | plate | | | | |
| Comparative | CFRP layered | — | 7 | 0/100 | 30 |
| Example 2 | plate | | | | |
| Comparative | CFRP layered | — | 7 | 0/100 | 30 |
| Example 3 | plate | | | | |

| | Molded article | | | | |
|---|---|---|---|---|---|
| | Dispersion | | | | |
| | as single | | | At drop test | |
| | fibers of | | | of electronic | Average fiber |
| | reinforcing | Convergence | | device housing | length of |
| | fibers | part E | | Presence or | reinforcing |
| | Presence | Presence or | Filling to | absence | fibers |
| | or absence | absence | details | of crack | [mm] |
| Example 1 | Present | Present | Good | Good | 0.3 |
| | | | (Filling to | (Cracks did not | |
| | | | terminals) | occur.) | |
| Example 2 | Present | Present | Good | Good | 0.5 |
| | | | (Filling to | (Cracks did not | |
| | | | terminals) | occur.) | |
| Example 3 | Present | Present | Good | Good | 0.3 |
| | | | (Filling to | (Cracks did not | |
| | | | terminals) | occur.) | |
| Example 4 | Present | Present | Good | Good | 0.3 |
| | | | (Filling to | (Cracks did not | |
| | | | terminals) | occur.) | |
| Example 5 | Present | Present | Good | Good | 0.3 |
| | | | (Filling to | (Cracks did not | |
| | | | terminals) | occur.) | |
| Comparative | Present | Absent | Bad | Good | 1.0 |
| Example 1 | | | (Not-filling | (Cracks did not | |
| | | | to details) | occur.) | |
| Comparative | Absent | Present | Bad | Bad | 3.0 |
| Example 2 | | | (Chipping | (Cracks | |
| | | | at demolding) | occurred.) | |
| Comparative | Present | Absent | Good | Bad | 0.1 |
| Example 3 | | | (Filling to | (Cracks | |
| | | | terminals) | occurred.) | |

### INDUSTRIAL APPLICABILITY

A thin-walled molded article of a member for an electronic device housing having both strength and impact resistance can be obtained, and it can be broadly used for parts and housings of electric and electronic devices such as personal computers, office automation equipment, audio-visual equipment, and home appliances, but the range of applications is not limited to these.

1. A member for an electronic device housing comprising a plate-like component having a fiber-reinforced plastic and a thermoplastic resin component integrated with at least a part of a peripheral edge region of the plate-like component, wherein the thermoplastic resin component contains reinforcing fibers A and a thermoplastic resin D, a part of the reinforcing fibers A are dispersed as single fibers, and another part of the reinforcing fibers A are not dispersed as single fibers and are arranged randomly in a shape of a convergence part E formed from a plurality of single fibers.

2. The member for an electronic device housing according to claim 1, wherein a content of the reinforcing fibers A in the thermoplastic resin component is 1 to 50% by mass.

3. The member for an electronic device housing according to claim 1, wherein a resin H different from the thermoplastic resin D is attached to surfaces of the single fibers forming the convergence part E at an amount of 0.1 to 30% by mass with respect to 100% by mass of the reinforcing fibers A contained in the convergence part E.

4. The member for an electronic device housing according to claim 1, wherein an average fiber diameter of the single fibers in the reinforcing fibers A in the thermoplastic resin component is 4.0 to 30.0 μm.

5. The member for an electronic device housing according to claim 1, wherein the plate-like component is a sandwich structural body comprising a core material and a fiber-reinforced plastic joined to both surfaces of the core material.

6. The member for an electronic device housing according to claim 1, wherein the reinforcing fibers A contain two kinds of reinforcing fibers B and reinforcing fibers C different from each other in average fiber diameter of single fibers, the reinforcing fibers B do not form the convergence part E, a part of the reinforcing fibers C disperse as single fibers, and another part of the reinforcing fibers C form the convergence part E.

7. The member for an electronic device housing according to claim 6, wherein a mass ratio B/C of the reinforcing fibers B to the reinforcing fibers C is 99/1 to 40/60.
